(19) United States
(12) Patent Application Publication
(10) Pub. No.: US 2015/0044424 A1
(43) Pub. Date: Feb. 12, 2015

(54) BOTTOM ELECTRODE AND MANUFACTURING METHOD THEREOF

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Xiaowei Jiang, Beijing (CN); Hongxi Xiao, Beijing (CN); Huafeng Liu, Beijing (CN); Hao Chen, Beijing (CN); Xiaohui Zhu, Beijing (CN)

(21) Appl. No.: 14/386,979

(22) PCT Filed: Apr. 24, 2013
(86) PCT No.: PCT/CN2013/074644

§ 371 Date: Sep. 22, 2014

(30) Foreign Application Priority Data
Feb. 19, 2013 (CN) 201310053249.4

(51) Int. Cl. H01J 37/32

(52) U.S. Cl. CPC H01J 37/32541; H01J 37/3255
USPC 428/172; 29/825

(57) ABSTRACT

A bottom electrode and a method of manufacturing the same are disclosed. The present invention relates to the field of dry etching, and has solved problems of separately fabrication of the ceramic points and ceramic layer of the conventional bottom electrode, low adhesion strength between the ceramic points and ceramic layer, incidental dropping off the ceramic layer. The bottom electrode includes: a metal substrate and an insulating layer disposed on the metal substrate, wherein the metal substrate comprises: a base substrate and a plurality of protrusion parts disposed on the base substrate, the insulating layer is disposed on surface of the base substrate and the protrusion parts on surface of the base substrate. Insulating protrusion points are formed at the protrusion parts.

### TECHNICAL FIELD

Embodiments of the present invention relate to the field of dry etching, particularly to a bottom electrode used for dry etching and a method of manufacturing thereof.

### BACKGROUND

A known display comprises an array substrate, a color filter substrate, and liquid crystal filled between the array substrate and the color filter substrate. Among them, both the array substrate and the color filter substrate comprise a glass substrate and a layered structure with a certain pattern disposed on the glass substrate. In known technologies, the layered structure is formed on the glass substrate by coating, exposure and etching, wherein the etching comprises dry etching and wet etching.

Dry etching is generally carried out in a vacuum environment to etch the glass substrate and the glass substrate is supported by a bottom electrode. As illustrated in FIG. 1, a known bottom electrode 01 comprises: a metal substrate 02 and a ceramic layer 3 disposed on the upper surface of the metal substrate 02 as well as ceramic points 4 protruding from the ceramic layer 3. In the dry etching process, static electricity is conducted to the metal substrate to bring the glass substrate into close contact with the bottom electrode by means of electrostatic adsorption. Also since dry etching is generally accomplished by plasma, and under a certain electric field, the ceramic layer serves to prevent the metal substrate from disturbing the electric field. The ceramic points are designed to support the glass substrate on the one hand and facilitate gas flow between the glass substrate and the bottom electrode on the other hand.

However in the dry etching process, the metal substrate has a certain temperature, and the etching duration is short. Since the distance from ceramic points to the metal substrate's surface is greater than the distance from the ceramic layer to the metal substrate's surface, temperature at ceramic points is lower than that of the ceramic layer, thus embossing spots are formed on the glass substrate, thereby influencing the display effect. Furthermore, known ceramic layer and ceramic points are formed by two step deposition, namely depositing a ceramic layer on the metal substrate first and then depositing ceramic points on the ceramic layer, which is a complex process. Further, since ceramic points and the ceramic layer are formed in different steps, bonding strength between the ceramic points and the ceramic layer is not high, causing ceramic points tend to drop off the ceramic layer.

### SUMMARY

Embodiments of the present invention provide a bottom electrode and a method of manufacturing thereof.

In accordance with one aspect of the present invention, there is provided a bottom electrode comprising a metal substrate and an insulating layer disposed on the metal substrate. The metal substrate comprises a base and a plurality of protrusion parts disposed on the base. The insulating layer overlays the base and the plurality of protrusion parts.

In one example, the insulating layer on an upper surface of the base has a thickness same as that of the insulating layer on upper surfaces of the protrusion parts.

In one example, a material for forming the insulating layer is ceramics, alumina or mica.

In one example, the upper surfaces of the protrusion parts are planar or curved surfaces.

In one example, the protrusion parts are arranged in an array on the base.

In one example, the protrusion parts and the base are formed integrally. Alternatively, the protrusion parts and the base are formed separately and then mounted together.

According to another aspect of the present invention, there is provided a method of manufacturing a bottom electrode, the method comprises:

forming a metal substrate with a plurality of protrusion parts; and

forming an insulating layer which overlays the metal substrate.

In one example, the metal substrate further comprises a base on which the plurality of protrusion parts are disposed.

In one example, the base and the plurality of protrusion parts are formed integrally. Alternatively, the base and the protrusion parts are formed separately and then mounted together.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a partial sectional structure diagram of a known bottom electrode;

FIG. 2 is a partial sectional structure diagram of a bottom electrode provided in an embodiment of the present invention;

FIG. 3 is a partial sectional structure diagram of a metal substrate of the bottom electrode illustrated in FIG. 2;

FIG. 4 is a partial sectional structure diagram of another bottom electrode provided in an embodiment of the present invention;

FIG. 5 is a sectional structure diagram of protruction parts provided in an embodiment of the present invention;

FIG. 6 is a method of manufacturing a bottom electrode provided in an embodiment of the present invention;

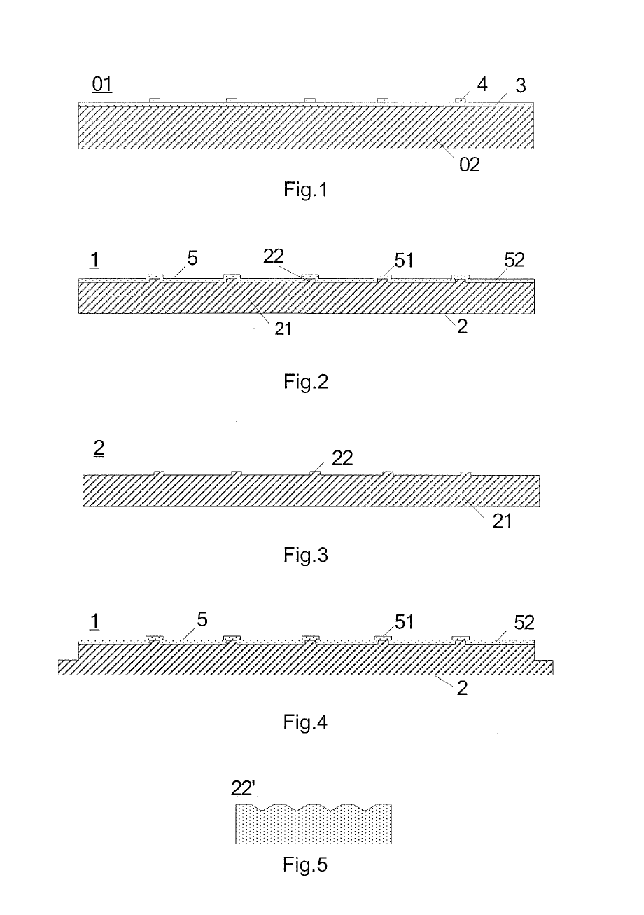

### REFERENCE NUMERALS

01,1-bottom electrode; 02,2-metal substrate; 3-ceramic layer; 4-ceramic point; 5-insulating layer; 21-base; 22,22′-protrusion part; 51-insulating protrusion point or protrusion part of insulating layer; 52-flat part of insulating layer.

### DETAILED DESCRIPTION

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. Based on the described embodiments herein, those skilled in the art can obtain other embodiment(s), without any inventive work, which should be within the scope of the invention.

Unless otherwise defined, all the technical and scientific terms used herein have the same meanings as commonly understood by one of ordinary skill in the art to which the present invention belongs. The terms “first,” “second,” etc., which are used in the description and the claims of the present application for invention, are not intended to indicate any sequence, amount or importance, but distinguish various components. Also, the terms such as “a,” “an,” etc., are not intended to limit the amount, but indicate the existence of at lease one. The terms “comprises,” “comprising,” “includes,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may comprise an electrical connection, directly or indirectly. “On,” “under,” “right,” “left” and the like are only used to indicate relative position relationship, and when the position of the object which is described is changed, the relative position relationship may be changed accordingly.

One embodiment of the present invention provides a bottom electrode 1 as illustrated in FIG. 2, comprising: a metal substrate 2 and an insulating layer 5 disposed on the metal substrate 2. The metal substrate 2 comprises: a base 21 and a plurality of protrusion parts 22 disposed on the base 21, as illustrated in FIG. 3. The insulating layer 5 overlays the base 21 and the protrusion parts 22, thereby forming insulating protrusion points 51 at the protrusion parts 22.

As illustrated in FIG. 4, the base 21 may also be of step-like shape as illustrated in FIG. 4, and protrusion parts 22 are disposed on the upper surface of the base 21 for carrying objects. Of course, the base 21 may also be of other shapes, and embodiments of the present invention will be described in detail with an example of rectangular base 21 illustrated in FIG. 3.

Since the insulating protrusion points 51 and the insulating layer are formed in a single process, the bonding strength is high, therefore ceramic points are not likely to drop off the ceramic layer as in the known technologies. Of course, the bottom electrode 1 may also be used in other processes such as film coating.

Generally, the materials for forming the base 21 and the protrusion parts 22 are the same and are metal, for example. The insulating layer 5 may be formed of insulating materials such as ceramics, alumina or mica, and in this embodiment, the material for forming the insulating layer 5 is ceramics.

In this embodiment, the insulating layer on the upper surface of the base 21 has a thickness same as that of the insulating layer on the upper surfaces of the protrusion parts 22. In this way, the distance from the upper surface of the insulating layer 5 to the upper surface of the metal substrate 2 is equal either at protrusion parts 51 or flat parts 52 of the insulating layer. Therefore, when the metal substrate 2 has a certain temperature, the protrusion parts 51 and the flat parts 52 have the same temperature. The dry etching may be used to etch the substrate supported by the bottom electrode 1 and avoid the problem of forming embossing spots on the surface of substrate due to different temperatures at protrusion parts 51 and flat parts 52 and in turn improve the display effect.

In this embodiment, upper surfaces of the protrusion parts 22 are planar surfaces. Thus, the insulating layer on surfaces of the protrusion parts 22 have a thickness same as that of the insulating layer on the surface of the metal substrate 2. Furtheimore, when the metal substrate 2 has a certain temperature, the temperature of the upper surfaces of the flat parts 52 of the insulating layer is the same as that of the upper surfaces of protrusion parts 51 of the insulating layer. In another embodiment, upper surfaces of the protrusion parts may also be curved or rough surfaces 22′, and are preferably curved or rough surfaces, such as saw teeth-like as illustrated in FIG. 5. When the protrusion parts 22′ have saw teeth-like surfaces, upper surfaces of insulating protrusion points formed on the metal substrate 2 are the same as that of the protrusion parts 22′, namely saw teeth-like surfaces illustrated in the figure. This saw teeth-like surface has advantages that on the one hand, during dry etching process, contact area is reduced due to multipoint contact between the insulating protrusion points and the glass substrate; and on the other hand, further coating an insulating layer on the protrusion parts 22′ can increase adhesion of the insulating layer against dropping off.

In this embodiment, the protrusion parts 22 are arranged in an array on the base 21. In this way, on the one hand it is in favor of circulation of gases between the glass substrate and the bottom electrode 1 during the dry etching process. On the other hand, the glass substrate placed on the bottom electrode 1 is under uniform stress, and would not be damaged due to non-uniform stress.

In this embodiment, the protrusion parts 22 and the base 21 may be formed integrally, or formed separately. However, the former is preferable, which can reduce manufacturing steps and costs. The “formed integrally” means formation by a single process without any subsequent processes. For example, it is possible to form the protrusion parts 22 and the base 21 by a single punching or molding. The “formed separately” means that the protrusion parts 22 and the base 21 are formed by two processes. For example, the protrusion parts 22 are formed by fabricating other layers on the base 21. For example, it is possible to form the protrusion parts 22 on the upper surface of the base 21 by soldering or other means.

Alternatively, the insulating layer 5 further overlays sides of the base 21 adjacent to the surface disposed with protrusion parts 22. To further prevent the metal substrate 2 from influencing the electric field during dry etching, the insulating layer 5 further overlays sides of the base 21 adjacent to the surface provided with protrusion parts 22, which can avoid dropping off of the insulating layer 5 in comparison to the case in which the insulating layer 5 only overlays the upper surface of the metal substrate 2.

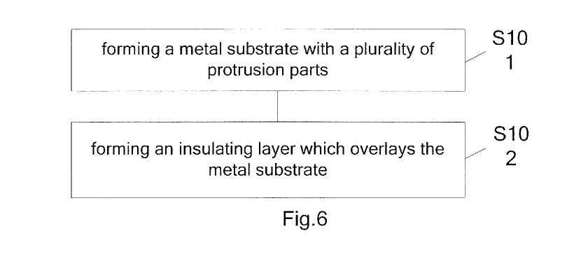

Another embodiment of the present invention provides a method of manufacturing a bottom electrode, as illustrated in FIG. 6, the method comprises:

Step S101, forming a metal substrate with protrusion parts.

In one example, as illustrated in FIG. 3, the metal substrate 2 comprises a base 21 and a plurality of protrusion parts 22 disposed on the base 21.

In one example, the base 21 and the protrusion parts 22 of the metal substrate 2 are formed by a single process. For example, they may be formed by a single punching or may be formed by a single molding. Alternatively, the base 21 and the protrusion parts 22 are first formed by different processes and then mounted together by soldering or other means.

Step S102, forming an insulating layer overlaying the metal substrate.

In one example, the insulating layer 5 overlays only the base 21 and the protrusion parts 22, thereby forming insulating protrusion points 51 at the protrusion parts 22, as illustrated in FIG. 2. In another example, it is also possible to form the insulating layer 5 further on sides of the metal substrate 2, which avoids dropping off of the insulating layer 5.

What are described above is related to the illustrative embodiments of the disclosure only and not limitative to the scope of the disclosure; the scopes of the disclosure are defined by the accompanying claims.

1. A bottom electrode comprising a metal substrate and an insulating layer disposed on the metal substrate, wherein the metal substrate comprises: a base and a plurality of protrusion parts disposed on the base, the insulating layer overlaying the base and the plurality of protrusion parts.

2. The bottom electrode of claim 1, wherein the insulating layer on an upper surface of the base has a thickness same as that of the insulating layer on upper surfaces of the protrusion parts.

3. The bottom electrode of claim 1, wherein a material for forming the insulating layer is ceramics, alumina or mica.

4. The bottom electrode of claim 1, wherein the upper surfaces of the protrusion parts are planar or curved surfaces.

5. The bottom electrode of claim 1, wherein the protrusion parts are arranged in an array on the base.

6. The bottom electrode of claim 1, wherein the protrusion parts and the base are formed integrally.

7. The bottom electrode of claim 1, wherein the protrusion parts and the base are formed separately and then mounted together.

8. A method of manufacturing a bottom electrode, comprising:
forming a metal substrate with a plurality of protrusion parts: and
forming an insulating layer which overlays the metal substrate.

9. The method of claim 8, wherein the metal substrate further comprises a base on which the plurality of protrusion parts are disposed.

10. The method of claim 9, wherein the base and the plurality of protrusion parts are formed integrally.

11. The method of claim 9, wherein the base and the protrusion parts are formed separately and then mounted together.

12. The bottom electrode of claim 2, wherein a material for forming the insulating layer is ceramics, alumina or mica.

13. The bottom electrode of claim 2, wherein the upper surfaces of the protrusion parts are planar or curved surfaces.

14. The bottom electrode of claim 2, wherein the upper surfaces of the protrusion parts are planar or curved surfaces.

15. The bottom electrode of claim 3, wherein the upper surfaces of the protrusion parts are planar or curved surfaces.

16. The bottom electrode of claim 2, wherein the protrusion parts are arranged in an array on the base.

17. The bottom electrode of claim 3, wherein the protrusion parts are arranged in an array on the base.

18. The bottom electrode of claim 4, wherein the protrusion parts are arranged in an array on the base.

19. The bottom electrode of claim 2, wherein the protrusion parts and the base are formed integrally,

20. The bottom electrode of claim 3, wherein the protrusion parts and the base are formed integrally.
